(19) United States
(12) Patent Application Publication
(10) Pub. No.: US 2018/0219041 A1
(43) Pub. Date: Aug. 2, 2018

(54) SOLID-STATE IMAGING DEVICE AND IMAGING APPARATUS

(71) Applicant: OLYMPUS CORPORATION, Tokyo (JP)

(72) Inventor: Yoshiaki Takemoto, Tokyo (JP)

(73) Assignee: OLYMPUS CORPORATION, Tokyo (JP)

(21) Appl. No.: 15/936,679

(22) Filed: Mar. 27, 2018

Related U.S. Application Data
(63) Continuation of application No. PCT/JP2015/079958, filed on Oct. 23, 2015.

(51) Int. Cl. H01L 27/146; H04N 5/369; H04N 5/232

(52) U.S. Cl. CPC H01L 27/14627; H04N 5/23212; H01L 27/14612; H04N 5/369

(57) ABSTRACT

A solid-state imaging device includes a first substrate and a second substrate stacked on the first substrate. The first substrate has a first semiconductor layer including a plurality of first photoelectric conversion elements and a plurality of openings. The second substrate has a second semiconductor layer including a plurality of second photoelectric conversion elements. The plurality of openings penetrate the first semiconductor layer. Each of the plurality of second photoelectric conversion elements is disposed in a region corresponding to any one of the plurality of openings.

### BACKGROUND OF THE INVENTION

### Field of the Invention

The present invention relates to a solid-state imaging device and an imaging apparatus.

This application is a continuation application based on international Patent Application No. PCT/JP2015/079958 filed on Oct. 23, 2015, the content of which is incorporated herein by reference.

### Description of Related Art

Video cameras, electronic still cameras, and the like have become widespread in general. For these cameras, charge coupled device (CCD) type and amplification type solid-state imaging devices have been used. In the amplification type solid-state imaging device, signal charges generated and accumulated by a photoelectric conversion element of a pixel on which light is incident are transmitted to an amplification unit provided in the pixel. The amplification type solid-state imaging device outputs a signal amplified by the amplification unit from the pixel. In the amplification type solid-state imaging device, a plurality of pixels configured in this manner are arranged in a two-dimensional matrix. A complementary metal oxide semiconductor (CMOS) type solid-state imaging device and the like which use a CMOS transistor are examples of the amplification type solid-state imaging device.

In a general CMOS type solid-state imaging device, a method of sequentially reading signal charges generated by photoelectric conversion elements of respective pixels arrayed in a two-dimensional matrix row by row is adopted. In the CMOS type solid-state imaging device having a general monolithic structure, that is, a structure fabricated from a single semiconductor substrate, circuits are disposed as follows. On a surface on which light is incident, peripheral circuits are disposed around a pixel array section which converts light into a signal charge. The peripheral circuits are vertical scanning circuits, horizontal scanning circuits, column processing circuits, output circuits, or the like. Wirings are disposed for each column or each row for transmission of an electric signal between the pixel array section and the peripheral circuits. On the other hand, in a current CMOS type solid-state imaging device, improvement of data rate, improvement of simultaneity of imaging in an imaging surface, and improvement of functions are required. However, in a CMOS type solid-state imaging device having the monolithic structure, it is difficult to improve performance due to limits on the density and the electric conduction velocity in a surface direction.

In view of the circumstances described above, the CMOS type solid-state imaging device having a structure in which a plurality of substrates are stacked has been proposed. In this CMOS type solid-state imaging device, photoelectric conversion elements and peripheral circuits can be distributed to the plurality of substrates. The plurality of substrates have a first substrate in which first photoelectric conversion elements are disposed and a second substrate in which second photoelectric conversion elements are disposed. With such a configuration, an increase in area occupied by pixels and improvement in functions can be realized.

Japanese Unexamined Patent Application, First Publication No. 2008-227250 discloses a solid-state imaging device in which a first solid-state imaging element and a second solid-state imaging element are stacked. The first solid-state imaging element receives incident fight and performs photoelectric conversion. The second solid-state imaging element receives light which has passed through the first solid-state imaging element and performs photoelectric conversion. At least one of the first solid-state imaging element and the second solid-state imaging element is configured as a back-surface irradiation solid-state imaging element. In the solid-state imaging device disclosed in Japanese Unexamined Patent Application, First Publication No. 2008-227250, an anti-reflection film is formed only on the upper surface of a first semiconductor layer on which light is incident regardless of whether the solid-state imaging device is a surface irradiation type or the back-surface irradiation type.

### SUMMARY OF THE INVENTION

According to a first aspect of the present invention, a solid-state imaging device includes a first substrate and a second substrate stacked on the first substrate. The first substrate has a first semiconductor layer including a plurality of first photoelectric conversion elements and a plurality of openings. The second substrate has a second semiconductor layer including a plurality of second photoelectric conversion elements. The plurality of openings penetrate the first semiconductor layer. Each of the second photoelectric conversion elements included in at least a portion of the plurality of second photoelectric conversion elements is disposed in a region corresponding to any one of the plurality of openings.

According to a second aspect of the present invention, in the first aspect, the first substrate may further include a light shielding film disposed in a region corresponding to a side surface of the opening.

According to a third aspect of the present invention, in the second aspect, the first semiconductor layer may include a first main surface and a second main surface. The second substrate may include a third main surface. A distance between the first main surface and the third main surface may be larger than a distance between the second main surface and the third main surface. The light shielding film may be disposed in a region corresponding to a portion of the first main surface.

According to a fourth aspect of the present invention, in any one of the first to third aspects, the first substrate may further include a transparent layer made of a transparent material filling the opening.

According to a fifth aspect of the present invention, in the first aspect, the first substrate may further include a plurality of first microlenses. Each of the plurality of first microlenses may be disposed at a position corresponding to one of the plurality of first photoelectric conversion elements. The first substrate may further include a plurality of second microlenses. Each of the plurality of second microlenses may be disposed at a position corresponding to one of the plurality of openings. A curvature of each of the plurality of second microlenses may be smaller than a curvature of each of the plurality of first microlenses.

According to sixth aspect of the present invention, in the first aspect, two or more of the second photoelectric conversion elements may be arranged in a region corresponding to any one of the plurality of openings.

According to a seventh aspect of the present invention, an imaging apparatus includes the solid-state imaging device.

### BRIEF DESCRIPTION OF THE DRAWINGS

FIG. 1 is a perspective view of a solid-state imaging device according to a first embodiment of the present invention.

FIG. 2 is a sectional view of the solid-state imaging device according to the first embodiment of the present invention.

FIG. 3 is a plan view of the solid-state imaging device according to the first embodiment of the present invention.

FIG. 4 is a sectional view of a solid-state imaging device according to a second embodiment of the present invention.

FIG. 5 is a sectional view of a solid-state imaging device according to a third embodiment of the present invention.

FIG. 6 is a plan view of the solid-state imaging device according to the third embodiment of the present invention.

FIG. 7 is a sectional view of a solid-state imaging device according to a fourth embodiment of the present invention.

FIG. 8 is a plan view of the solid-state imaging device according to the fourth embodiment of the present invention.

FIG. 9 is a sectional view of a solid-state imaging device according to a fifth embodiment of the present invention.

FIG. 10 is a sectional view of a solid-state imaging device according to a sixth embodiment of the present invention.

FIG. 11 is a block diagram showing a configuration of an imaging apparatus according to a seventh embodiment of the present invention.

### DETAILED DESCRIPTION OF THE INVENTION

Embodiments of the present invention will be described with reference to drawings.

### First Embodiment

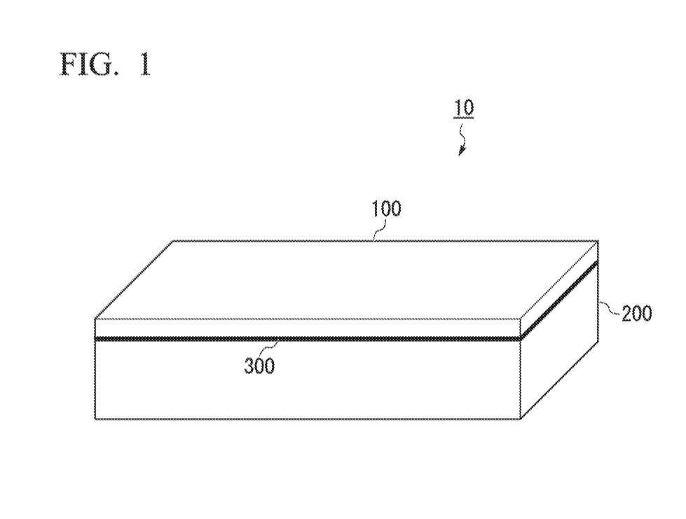

FIG. 1 shows a configuration of a solid-state imaging device 10 according to a first embodiment of the present invention. As shown in FIG. 1, the solid-state imaging device 10 includes a first substrate 100, a second substrate 200, and a connection layer 300. The first substrate 100 and the second substrate 200 are stacked through the connection layer 300.

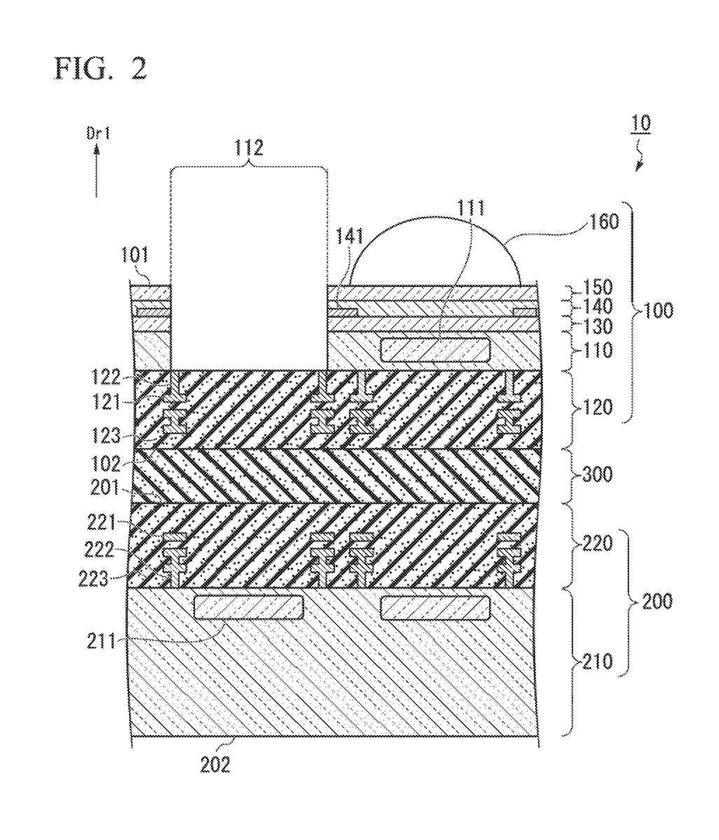

FIG. 2 shows a configuration of the solid-state imaging device 10. In FIG. 2, a partial cross-section of the solid-state imaging device 10 is shown. The dimensions of parts constituting the solid-state imaging device 10 need not conform to the dimensions shown in FIG. 2. The dimensions of parts constituting the solid-state imaging device 10 may be arbitrary. The same applies to dimensions in sectional views other than FIG. 2.

The first substrate 100 and the second substrate 200 are stacked in a thickness direction Dr1 of the first substrate 100. The thickness direction Dr1 of the first substrate 100 is a direction perpendicular to a first surface 101 of the first substrate 100.

The first substrate 100 includes a first semiconductor layer 110, a first wiring layer 120, an anti-reflection film 130, a transparent resin layer 140, a color filter 150, and a plurality of first microlenses 160. In FIG. 2, one first microlens 160 is shown as a representative. The first semiconductor layer 110, the first wiring layer 120, the anti-reflection film 130, the transparent resin layer 140, and the color filter 150 are stacked in the thickness direction Dr1 of the first substrate 100.

The first semiconductor layer 110 is made of a first semiconductor material. For example, the first semiconductor material is at least one of silicon (Si), germanium (Ge), gallium (Ga), arsenic (As), boron (B), and the like. The first semiconductor layer 110 is in contact with the first wiring layer 120 and the anti-reflection film 130. The first semiconductor layer 110 has a plurality of first photoelectric conversion elements 111. In FIG. 2, one first photoelectric conversion element 111 is shown. For example, the first photoelectric conversion element 111 is made of a semiconductor material whose impurity concentration is different from that of the first semiconductor material constituting the first semiconductor layer 110. The first photoelectric conversion element 111 converts light into a signal.

The first wiring layer 120 is in contact with the first semiconductor layer 110 and the connection layer 300. The first wiring layer 120 has two surfaces. A surface of the first wiring layer 120 which is in contact with the connection layer 300 constitutes a second surface 102 of the first substrate 100. The first surface 101 and the second surface 102 are main surfaces of the first substrate 100. The main surfaces of the first substrate 100 are relatively wide surfaces among a plurality of surface of the first substrate 100. The first surface 101 and the second surface 102 face in opposite directions.

The first wiring layer 120 includes a first wiring 121, a first via 122, and a first interlayer insulation film 123. There are a plurality of first wirings 121, but a reference numeral of one first wiring 121 is shown as a representative in FIG. 2. There are a plurality of first vias 122, but a reference numeral of one first via 122 is shown as a representative in FIG. 2.

The first wiring 121 and the first via 122 are made of a first conductive material. For example, the first conductive material is a metal such as aluminum (Al) or copper (Cu). The first wiring 121 and the first via 122 may be made of different conductive materials. The first wiring 121 is a thin film on which a wiring pattern is formed. The first wiring 121 transmits a signal generated by the first photoelectric conversion element 111. Only one layer of the first wiring 121 may be disposed, or a plurality of layers of the first wiring 121 may be disposed. Three layers of the first wiring 121 are disposed in the example shown in FIG. 2.

The first via 122 is in contact with the first wiring 121 of different layers. In the first wiring layer 120, a portion other than the first wiring 121 and the first via 122 is composed of the first interlayer insulation film 123. The first interlayer insulation film 123 is made of a first insulation material. For example, the first insulation material is at least one of silicon dioxide (SiO2), an oxide of silicon containing carbon (SiOC), silicon nitride (SiN), and the like.

At least one of the first semiconductor layer 110 and the first wiring layer 120 may have a circuit element such as a transistor.

The anti-reflection film 130 is in contact with the first semiconductor layer 110 and the transparent resin layer 140. The anti-reflection film 130 suppresses reflection of light incident on the first semiconductor layer 110. The transparent resin layer 140 is in contact with the anti-reflection film 130 and the color filter 150. The transparent resin layer 140 has a light shielding film 141. There are a plurality of light shielding films 141, but a reference numeral of one light shielding film 141 is shown as a representative in FIG. 2. For example, a main component of the light shielding film 141 is a metal such as gold (Au), aluminum (Al), or tungsten (W). The light shielding film 141 may include an adhesion layer. For example, the adhesion layer of the light shielding film 141 is a metal such as titanium (Ti), chromium (Cr), or the like. The light shielding film 141 reflects portion of light incident on the transparent resin layer 140. As a result, light which has not passed through the first microlens 160 and is incident on the first photoelectric conversion element 111 is suppressed.

The color filter 150 is in contact with the transparent resin layer 140 and the first microlens 160. The color filter 150 has two surfaces. A surface of the color filter 150 in contact with the first microlens 160 constitutes the first surface 101 of the first substrate 100. The color filter 150 transmits light in a specific wavelength range. The plurality of first microlenses 160 are arranged on the first surface 101 of the first substrate 100. Each of the plurality of first microlenses 160 is disposed at a position corresponding to one of the plurality of first photoelectric conversion elements 111. The plurality of first microlenses 160 forms an image based on light. The plurality of first microlens 160 are disposed above the first semiconductor layer 110a in FIG. 2. In a case in which the anti-reflection film 130, the transparent resin layer 140, and the color filter 150 are not included in the solid-state imaging device 10, the plurality of first microlens 160 are disposed on the first semiconductor layer 110.

The first semiconductor layer 110, the first wiring layer 120, the anti-reflection film 130, the transparent resin layer 140, and the color filter 150 include a plurality of openings 112. In FIG. 2, one opening 112 is shown as a representative. The opening 112 penetrates the first semiconductor layer 110, the anti-reflection film 130, the transparent resin layer 140, and the color filter 150 in the thickness direction Dr1 of the first substrate 100. The opening 112 has only to penetrate at least the first semiconductor layer 110. The opening 112 is formed by removing some regions in each of the first semiconductor layer 110, the anti-reflection film 130, the transparent resin layer 140, and the color filter 150. The opening 112 includes side surfaces of each of the first semiconductor layer 110, the anti-reflection film 130, the transparent resin layer 140, and the color filter 150, and includes a surface of the first wiring layer 120.

The second substrate 200 includes a second semiconductor layer 210 and a second wiring layer 220. The second semiconductor layer 210 and the second wiring layer 220 are stacked in the thickness direction Dr1 of the first substrate 100.

The second semiconductor layer 210 is made of a second semiconductor material. The second semiconductor material is the same as the first semiconductor material constituting the first semiconductor layer 110. Alternatively, the second semiconductor material is different from the first semiconductor material. For example, the second semiconductor material is at least one of silicon (Si), germanium (Ge), gallium (Ga), arsenic (As), boron (B), and the like. The second semiconductor layer 210 is in contact with the second wiring layer 220. The second semiconductor layer 210 has two surfaces. A surface of the second semiconductor layer 210 on the opposite side to another surface of the second semiconductor layer 210 in contact with the second wiring layer 220 constitutes a second surface 202 of the second substrate 200.

The second semiconductor layer 210 includes a plurality of second photoelectric conversion elements 211. In FIG. 2, a reference numeral of one second photoelectric conversion element 211 is shown as a representative. For example, the second photoelectric conversion element 211 is made of a semiconductor material whose impurity concentration is different from that of the second semiconductor material constituting the second semiconductor layer 210. The second photoelectric conversion element 211 converts light into a signal.

The second wiring layer 220 is in contact with the second semiconductor layer 210 and the connection layer 300. The second wiring layer 220 has two surfaces. A surface of the second wiring layer 220 in contact with the connection layer 300 constitutes a first surface 201 of the second substrate 200. The first surface 201 and the second surface 202 are main surfaces of the second substrate 200. The main surfaces of the second substrate 200 are relatively wide surfaces among a plurality of surfaces of the second substrate 200. The first surface 201 and the second surface 202 face in opposite directions.

The second wiring layer 220 includes a second wiring 221, a second via 222, and a second interlayer insulation film 223. There are a plurality of second wirings 221, but a reference numeral of one second wiring 221 is shown as a representative in FIG. 2. There are a plurality of second vias 222, but a reference numeral of one second via 222 is shown as a representative in FIG. 2.

The second wiring 221 and the second via 222 are made of a second conductive material. The second conducive material is the same as the first conductive material constituting the first wiring 121 and the first via 122. Alternatively, the second conductive material is different from the first conductive material. For example, the second conductive material is a metal such as aluminum (Al), copper (Cu), or the like. The second wiring 221 and the second via 222 may be made of different conductive materials. The second wiring 221 is a thin film on which a wiring pattern is formed. The second wiring 221 transmits a signal generated by the second photoelectric conversion element 211. Only one layer of the second wiring 221 may be disposed, or a plurality of layers of the second wiring 221 may be disposed in the example shown n FIG. 2, three layers of the second wiring 221 are disposed.

The second via 222 connects different layers of the second wiring 221. A portion other than the second wiring 221 and the second via in the second wiring layer 220 is constituted by the second interlayer insulation film 223. The second interlayer insulation film 223 is made of a second insulation material. The second insulation material is the same as the first insulation material constituting the first interlayer insulation film 123. Alternatively, the second insulation material is different from the first insulation material. For example, the second insulation material is at least one of silicon dioxide (SiO2), an oxide of silicon containing carbon (SiOC), silicon nitride (SiN), and the like.

At least one of the second semiconductor layer 210 and the second wiring layer 220 may include a circuit element such as transistor.

The connection layer 300 is disposed between the first substrate 100 and the second substrate 200. The connection layer 300 is in contact with the first substrate 100 and the second substrate 200. For example, the connection layer 300 is made of at least one of silicon dioxide (SiO2), an oxide of silicon containing carbon (SiOC), silicon nitride (SiN), and the like. Alternatively, the connection layer 300 is made of a resin material. The connection layer 300 connects the first substrate 100 and the second substrate 200. The connection layer 300 transmits light which has passed through the first substrate 100.

The connection layer 300 may include a filter region which transmits light in a specific wavelength range. For example, a resin containing a pigment or dye may be disposed in some regions of the connection layer 300. Alternatively, a Fabry-Perot filter including an arbitrary insulator and metal films interposing the insulator may be disposed in some regions of the connection layer 300. When the connection layer 300 has a filter region, the solid-state imaging device 10 can allow only light in a specific wavelength range to be incident on the second photoelectric conversion element 211.

The connection layer 300 does not electrically connect the first substrate 100 and the second substrate 200. However, the connection layer 300 may electrically connect the first substrate 100 and the second substrate 200. For example, signals generated by the plurality of first photoelectric conversion elements 111 may be transmitted to the second substrate 200 through the connection layer 300. Alternatively, signals generated by the plurality of second photoelectric conversion elements 211 may be transmitted to the first substrate 100 through the connection layer 300.

Light from a subject which has passed through an imaging lens disposed optically in front of the solid-state imaging device 10 is incident on the first microlens 160. The first microlens 160 forms an image based on light which has passed through the imaging lens. The light which has passed through the first microlens 160 is incident on the color filter 150. The color filter 150 transmits light in a specific wavelength range.

The light which has passed through the color filter 150 passes through the transparent resin layer 140 and the anti-reflection film 130, and is incident on the first semiconductor layer 110. The first photoelectric conversion element 111 of the first semiconductor layer 110 is disposed in a region corresponding to the first microlens 160. In other words, the first photoelectric conversion element 111 is disposed in a region which transmits the light which has passed through the first microlens 160. The light incident on the first semiconductor layer 110 is incident on the first photoelectric conversion element 111. The first photoelectric conversion element 111 converts the incident light into a signal.

Light which has passed through the first photoelectric conversion element 111 is incident an the first wiring layer 120. The first wiring 121 is disposed so as not to shield most of the light which has passed through the first photoelectric conversion element 111. The light incident on the first wiring layer 120 passes through the first wiring layer 120 and the connection layer 300, and is incident on the second wiring layer 220. The second wiring 221 is disposed so as not to shield most of the light which has passed through the first photoelectric conversion element 111. The light incident on the second wiring layer 220 passes through the second wiring layer 220 and is incident the second semiconductor layer 210. The second photoelectric conversion element 211 of the second semiconductor layer 210 is disposed in a region corresponding to the first microlens 160 and the first photoelectric conversion element 111. In other words, the second photoelectric conversion element 211 is disposed in a region transmitting light which has passed through the first microlens 160 and the first photoelectric conversion element 111. Light incident on the second semiconductor layer 210 is incident on the second photoelectric conversion element 211. The second photoelectric conversion element 211 converts the incident light into a signal.

On the other hand, light incident on the opening 112 passes through the opening 112 and is incident on the first wiring layer 120. The first wiring 121 is disposed so as not to shield most of the light which has passed through the opening 112. The light incident on the first wiring layer 120 is incident on the second semiconductor layer 210 in the same manner as described above. The second photoelectric conversion element 211 of the second semiconductor layer 210 is disposed in a region corresponding to the opening 112. That is, the second photoelectric conversion element 211 is disposed in a region transmitting the light which has passed through the opening 112. The light incident on the second semiconductor layer 210 is incident on the second photoelectric conversion element 211. The second photoelectric conversion element 211 converts the incident light into a signal.

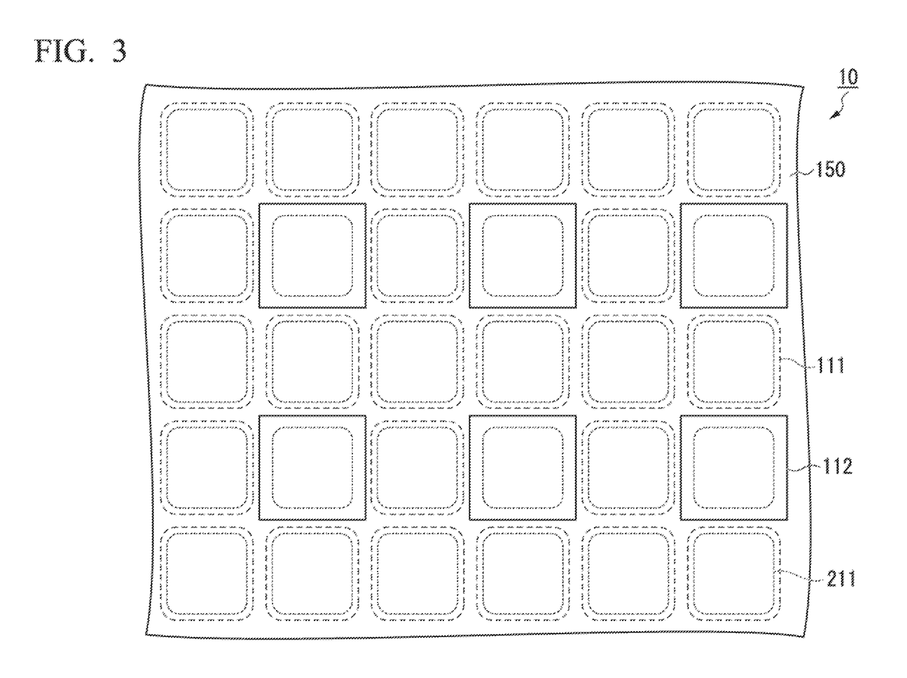

FIG. 3 shows an array of the plurality of first photoelectric conversion elements 111, the plurality of second photoelectric conversion elements 211, and the plurality of openings 112. FIG. 3 shows the array when the solid-state imaging device 10 is viewed in the direction perpendicular to the first surface 101 of the first substrate 100. That is, FIG. 3 shows the array when the front of the first substrate 100 of the solid-state imaging device 10 is viewed.

In FIG. 3, a surface of the color filter 150 is shown. The plurality of first microlenses 160 is omitted in FIG. 3. Reference numerals of one first photoelectric conversion element 111, one second photoelectric conversion element 211, and one opening 112 are shown as representatives in FIG. 3. The plurality of first photoelectric conversion elements 111, the plurality of second photoelectric conversion elements 211, and the plurality of openings 112 are arranged in a matrix. These have square shapes. The shapes of these need not be square. For example, the shapes of these may be circular or polygonal.

When the solid-state imaging device 10 is viewed in the direction perpendicular to the first surface 101 of the first substrate 100, each of the plurality of second photoelectric conversion elements 211 overlaps any one of the first photoelectric conversion element 111 and the opening 112. One first photoelectric conversion element 111 and one second photoelectric conversion element 211 correspond to each other. One opening 112 and one second photoelectric conversion element 211 correspond to each other. When the solid-state imaging device 10 is viewed in the direction perpendicular to the first surface 101 of the first substrate 100, the center of the first photoelectric conversion element 111 coincides with the center of the second photoelectric conversion element 211, and the center of the opening 112 coincides with the center of the second photoelectric conversion element 211. Arrangement intervals of the plurality of first photoelectric conversion elements 111 are the same as arrangement intervals of the plurality of second photoelectric conversion elements 211.

In the solid-state imaging device 10, the second photoelectric conversion element 211 is disposed in a region corresponding to the first photoelectric conversion element 111 and a region corresponding to the opening 112. However, the second photoelectric conversion element 211 need not be disposed in a region corresponding to the first photoelectric conversion element 111.

As described above, the solid-state imaging device 10 includes the first substrate 100 and the second substrate 200 stacked on the first substrate 100. The first substrate 100 includes the first semiconductor layer 110 having the plurality of first photoelectric conversion elements 111 and the plurality of openings 112. The second substrate 200 includes the second semiconductor layer 210 having the plurality of second photoelectric conversion elements 211. The plurality of openings 112 penetrate the first semiconductor layer 110. Each second photoelectric conversion element 211 included in at least a portion of the plurality of second photoelectric conversion elements 211 is disposed in a region corresponding to any one of the plurality of openings 112.

A small amount of impurity material is added to the first semiconductor material constituting the first semiconductor layer 110. For example, the impurity material is at least one of arsenic, phosphorus, and boron. For this reason, the first semiconductor layer 110 absorbs at least a portion of visible light. Since light does not pass through the first semiconductor layer 110 in a region in which the opening 112 is provided, the light is not absorbed by the first semiconductor layer 110. For this reason, the solid-state imaging device 10 can increase the amount of light incident on the second photoelectric conversion element 211.

Each of the plurality of first photoelectric conversion elements 111 constitutes a first pixel. Each of the plurality of second photoelectric conversion elements 211 constitutes a second pixel. The solid-state imaging device 10 includes a reading circuit, a signal processing circuit, and a driving circuit. The reading circuit reads a signal from each of the first pixel and the second pixel. The signal processing circuit performs amplification, analog to digital conversion (AD conversion), and the like on a signal read from each of the first pixel and the second pixel. The driving circuit drives a circuit including the first pixel and the second pixel. The reading circuit, the signal processing circuit, and the driving circuit are arranged in at least one of the first substrate 100 and the second substrate 200. The reading circuit, the signal processing circuit, and the driving circuit are arranged so that the first pixel and the second pixel may operate independently from each other.

For example, the plurality of first photoelectric conversion elements 111 and the plurality of second photoelectric conversion elements 211 can acquire a signal based on light in a visible light band. As a result, the solid-state imaging device 10 can acquire a color image signal.

The solid-state imaging device 10 may acquire a color image signal and an image signal of special light at the same time. The plurality of first photoelectric conversion elements 111 can acquire a signal based on the light in a visible light band. The plurality of second photoelectric conversion elements 211 can acquire a signal based on the special light.

For example, the special light is fluorescence. In the medical field, observation of a lesion part using a color image and a fluorescent image is performed. For example, excitation light is emitted to indocyanine green (ICG) and fluorescence from a lesion part is detected. ICG is a fluorescent substance. ICG is administered into the body of a person who is to undergo examination in advance. The ICG is excited in an infrared region by excitation light and emits fluorescence. The administered ICG is accumulated in a lesion such as cancer. Since strong fluorescence is generated from the lesion, an examiner can determine whether there is a lesion on the basis of an imaged fluorescent image. The connection layer 300 is configured to transmit only fluorescence. The plurality of second photoelectric conversion elements 211 generate a signal based on the fluorescence.

The special light may be narrow band light. It is possible to acquire an image in which blood vessels are emphasized by irradiating blood vessels with light of a wavelength which is easily absorbed by hemoglobin in blood. For example, blood vessels are irradiated with blue narrow band light or green narrow band light. The connection layer 300 is configured to transmit only narrow band light. The plurality of second photoelectric conversion elements 211 generate a signal based on the narrow band light.

The solid-state imaging device of each aspect of the present invention need not include a constituent corresponding to at least one of the first wiring layer 120, the anti-reflection film 130, the transparent resin layer 140, the color filter 150, the plurality of first microlenses 160, the second wiring layer 220, and the connection layer 300.

In the first embodiment, each of the plurality of second photoelectric conversion elements 211 is disposed in a region corresponding to any one of the plurality of openings 112. For this reason, light which has passed through the opening 112 is likely to be incident on the second photoelectric conversion element 211. As a result, the solid-state imaging device 10 can increase the amount of light incident on the second photoelectric conversion element 211.

### Second Embodiment

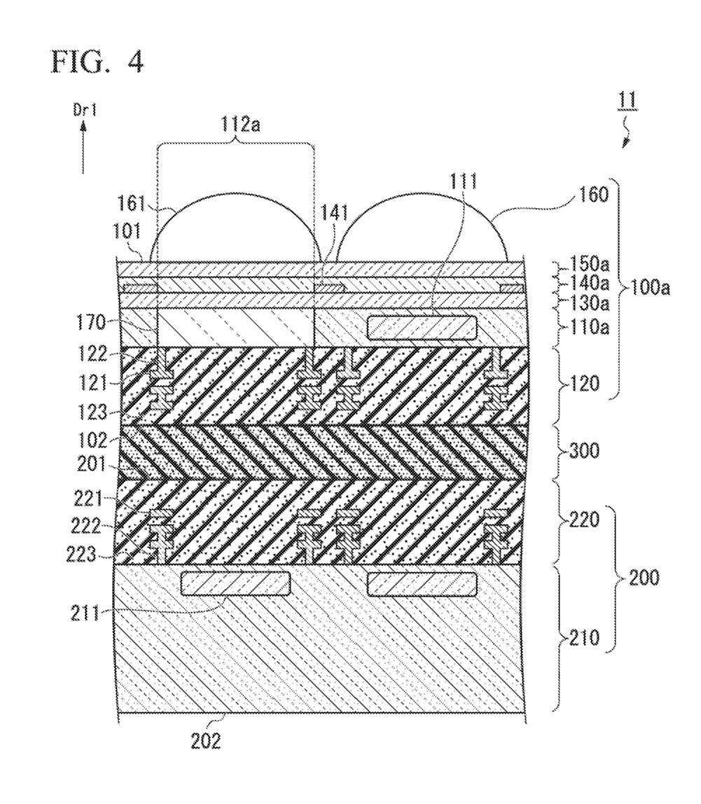

FIG. 4 shows a configuration of a solid-state imaging device 11 according to a second embodiment of the present invention. In FIG. 4, a partial cross-section of the solid-state imaging device 11 is shown. With respect to the configuration shown in FIG. 4, a difference from the configuration shown in FIG. 2 will be described.

In FIG. 4, the first substrate 100 in FIG. 2 is changed to a first substrate 100a. The first semiconductor layer 110 in the first substrate 100 is changed to a first semiconductor layer 110a in the first substrate 100a. The anti-reflection film 130 in the first substrate 100 is changed to an anti-reflection film 130a in the first substrate 100a. The transparent resin layer 140 in the first substrate 100 is changed to a transparent resin layer 140a in the first substrate 100a. The color filter 150 in the first substrate 100 is changed to a color filter 150a in the first substrate 100a.

The opening 112 in the first substrate 100 is changed to an opening 112a in the first substrate 100a. The opening 112a penetrates the first semiconductor layer 110a in the thickness direction Dr1 of the first substrate 100a. The opening 112a is formed by removing some regions in the first semiconductor layer 110a. The opening 112a includes side surfaces of the first semiconductor layer 110a and a surface of the first wiring layer 120. The opening 112a is not disposed in the anti-reflection film 130a, the transparent resin layer 140a, and the color filter 150a.

The first semiconductor layer 110a includes a plurality of first photoelectric conversion elements 111. The first substrate 100a further includes the transparent layer 170 made of a transparent material filling the opening 112a. For example, the transparent material constituting the transparent layer 170 is at least one of silicon dioxide (SiO2), silicon nitride (SiN), and a resin material. A light absorption coefficient of the transparent layer 170 is smaller than a light absorption coefficient of the first semiconductor layer 110a. As a result, the transparent layer 170 does not absorb light as easily as the first semiconductor layer 110a.

The first substrate 100a includes a plurality of second microlenses 161. Each of the plurality of second microlenses 161 is disposed at a position corresponding to one of the plurality of openings 112a. The plurality of second microlenses 161 are arranged on the first surface 101 of the first substrate 100a. Each of the plurality of second microlenses 161 is disposed at a position corresponding to one of the plurality of second photoelectric conversion elements 211. The plurality of second microlenses 161 forms an image based on light. The plurality of second microlenses 161 are disposed above the first semiconductor layer 110a in FIG. 4. In a case in which the anti-reflection film 130a, the transparent resin layer 140a, and the color filter 150a are not included in the solid-state imaging device 11, the plurality of second microlenses 161 are disposed on the first semiconductor layer 110a.

Except for the points described above, the configuration shown in FIG. 4 is the same as the configuration shown in FIG. 2.

The light from a subject which has passed through the imaging lens disposed optically in front of the solid-state imaging device 11 is incident on the second microlens 161. The second microlens 161 forms an image based on light which has passed through the imaging lens. The light which has passed through the second microlens 161 is incident on the color filter 150a. The color filter 150a transmits light in a specific wavelength range. The wavelength of light transmitted through the color filter 150a in a region corresponding to the first microlens 160 and the wavelength of light transmitted through the color filter 150a in a region corresponding to the second microlens 161 may be different from each other.

The light which has passed through the color filter 150a passes through the transparent resin layer 140a and the anti-reflection film 130a, and is incident on the transparent layer 170. The light incident on the transparent layer 170 passes through the transparent layer 170 and is incident on the first wiring layer 120. The first wiring 121 is disposed so as not to shield most of the light which has passed through the transparent layer 170. The light incident on the first wiring layer 120 passes through the first wiring layer 120 and the connection layer 300, and is incident on the second wiring layer 220. The second wiring 221 is disposed so as not to shield most of the light which has passed through the transparent layer 170. The light incident on the second wiring layer 220 passes through the second wiring layer 220 and is incident on the second semiconductor layer 210. The second photoelectric conversion element 211 of the second semiconductor layer 210 is disposed in a region corresponding to the second microlens 161 and a region corresponding to the transparent layer 170. In other words, the second photoelectric conversion element 211 is disposed in a region transmitting the light which has passed through the second microlens 161 and the transparent layer 170. The light incident on the second semiconductor layer 210 is incident on the second photoelectric conversion element 211. The second photoelectric conversion element 211 converts the incident light into a signal.

An array of the plurality of first photoelectric conversion elements 111, the plurality of second photoelectric conversion elements 211, and the plurality of openings 112a is the same as the array shown in FIG. 3.

In the solid-state imaging device 11, the second photoelectric conversion element 211 is disposed in a region corresponding to the first photoelectric conversion element 111 and a region corresponding to the opening 112a. However, the second photoelectric conversion element 211 need not be disposed in a region corresponding to the first photoelectric conversion element 111.

The solid-state imaging device according to each aspect of the present invention need not include a constituent corresponding to at least one of the anti-reflection film 130a, the transparent resin layer 140a, the color filter 150a, and the plurality of second microlenses 161.

In the second embodiment, each of the plurality of second photoelectric conversion elements 211 is disposed in a region corresponding to any one of the plurality of openings 112a. For this reason, light which has passed through the opening 112a, that is, light which has passed through the transparent layer 170, is likely to be incident on the second photoelectric conversion element 211. As a result, the solid-state imaging device 11 can increase the amount alight incident on the second photoelectric conversion element 211.

In the second embodiment, the transparent layer 170 is disposed in the opening 112a. For this reason, the second microlens 161 can be arranged on the first surface 101 of the first substrate 100a. As a result, the solid-state imaging device 11 can increase the amount of light incident on the second photoelectric conversion element 211.

### Third Embodiment

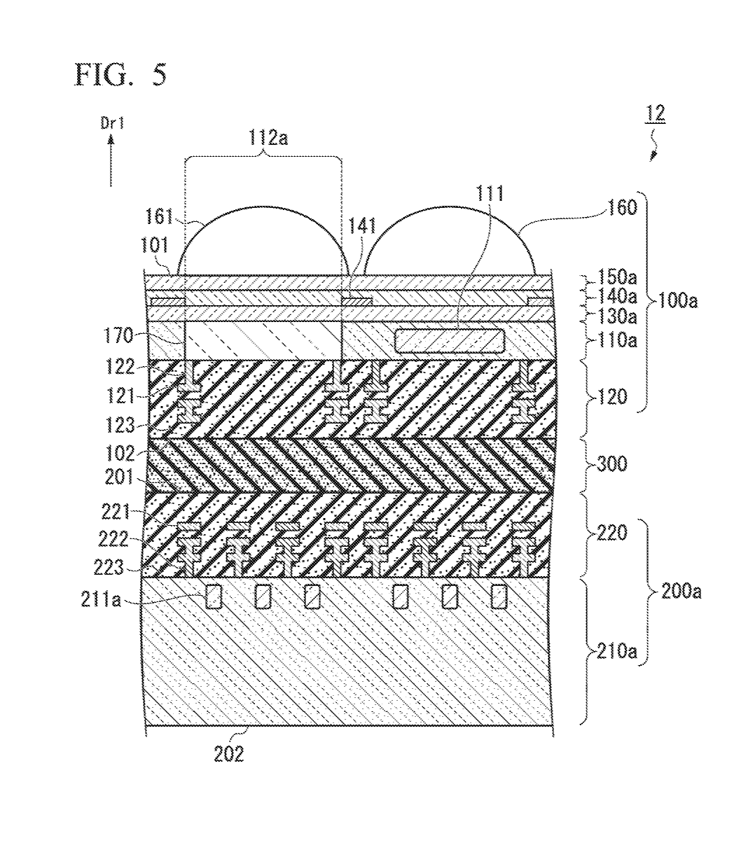

FIG. 5 shows a configuration of a solid-state imaging device 12 according to a third embodiment of the present invention. FIG. 5 shows a partial cross-section of the solid-state imaging device 12. With respect to the configuration shown in FIG. 5, a difference from the configuration shown in FIG. 4 will be described.

In FIG. 5, the second substrate 200 in FIG. 4 is changed to a second substrate 200a. The second semiconductor layer 210 of the second substrate 200 is changed to a second semiconductor layer 210a in the second substrate 200a. The second semiconductor layer 210a includes a plurality of second photoelectric conversion elements 211a. In FIG. 5, a reference numeral of one second photoelectric conversion element 211a is shown as a representative.

Two or more second photoelectric conversion elements 211a are arranged to correspond to each of the plurality of first microlenses 160 and each of the plurality of first photoelectric conversion elements 111. For this reason, light which has passed through the first microlens 160 and the first photoelectric conversion element 111 is incident on the two or more second photoelectric conversion elements 211a. In addition, two or more second photoelectric conversion elements 211a are arranged to correspond to each of the plurality of openings 112a. For this reason, light which has passed through the opening 112a is incident on the two or more second photoelectric conversion elements 211a. Positions of each of the plurality of second photoelectric conversion elements 211a in a direction parallel to the first surface 101 of the first substrate 100a are different. A wiring pattern of the second wiring 221 is different from the wiring pattern of the second wiring 221 in FIG. 4.

Except for the points described above, the configuration shown in FIG. 5 is the same as the configuration shown in FIG. 4.

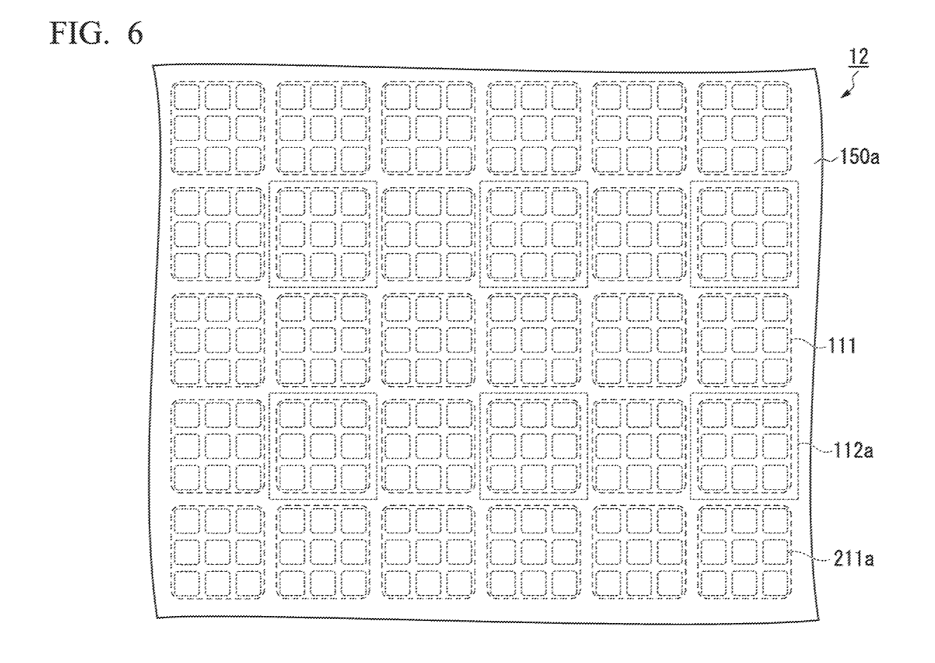

FIG. 6 shows an array of the plurality of first photoelectric conversion elements 111, the plurality of second photoelectric conversion elements 211a, and the plurality of openings 112a. FIG. 6 shows the array when the solid-state imaging device 12 is viewed in a direction perpendicular to the first surface 101 of the first substrate 100a. That is, FIG. 6 shows the array when the front of the first substrate 100a of the solid-state imaging device 12 is viewed.

With respect to the configuration shown in FIG. 6, a difference from the configuration shown in FIG. 3 will be described. One first photoelectric conversion element 111 and a group of six second photoelectric conversion elements 211a correspond to each other. That is, when the solid-state imaging device 12 is viewed in the direction perpendicular to the first surface 101 of the first substrate 100a, six second photoelectric conversion elements 211 overlap one first photoelectric conversion element 111. One opening 112a and a group of six second photoelectric conversion elements 211a correspond to each other. That is, when the solid-state imaging device 12 is viewed in a direction perpendicular to the first surface 101 of the first substrate 100a, six second photoelectric conversion elements 211 overlap one opening 112a. The number of the second photoelectric conversion elements 211a corresponding to one first photoelectric conversion element 111 and one opening 112a has only to be two or more. The arrangement intervals of the plurality of first photoelectric conversion elements 111 are different from the arrangement intervals of the plurality of second photoelectric conversion elements 211a. The arrangement intervals of the plurality of second photoelectric conversion elements 211a are smaller than the arrangement intervals of the plurality of first photoelectric conversion elements 111.

Except for the points described above, the configuration shown in FIG. 6 is the same as the configuration shown in FIG. 5.

In the solid-state imaging device 12, the second photoelectric conversion element 211a is disposed in a region corresponding to the first photoelectric conversion element 111 and a region corresponding to the opening 111a. However, the second photoelectric conversion element 211 need not be disposed in a region corresponding to the first photoelectric conversion element 111.

The plurality of second photoelectric, conversion elements 211a are arranged to correspond to one first microlens 160 or one second microlens 161. For this reason, as will be described below, the second photoelectric conversion element 211a can function as an image surface phase difference autofocus pixel.

Light collected by the first microlens 160 and the second microlens 161 forms a two-dimensional distribution in accordance with directivity of light, that is, a direction of light. This distribution depends on a focal position of an imaging lens and a position of an imaging object. The solid-state imaging device 12 detects light using the second photoelectric conversion elements 211a arranged at a plurality of different positions in a region corresponding to the first microlens 160 or the second microlens 161. The solid-state imaging device 12 generates a signal in accordance with detected light. It is possible to estimate the distribution described above by processing this signal. That is, it is possible to estimate a position of an imaging object with respect to a focal position of an imaging lens. It is possible to adjust the focal position of an imaging lens in accordance with a result of the estimation.

In the third embodiment, each of the plurality of second photoelectric conversion elements 211a is disposed in a region corresponding to any one of the plurality of openings 112a. For this reason, the light which has passed through the opening 112a, that is, the light which has passed through the transparent layer 170, is likely to be incident on the second photoelectric conversion element 211a. As a result, the solid-state imaging device 12 can increase the amount of light incident on the second photoelectric conversion element 211a.

In the third embodiment, two or more second photoelectric conversion elements 211a are arranged in a region corresponding to any one of the plurality of openings 112a. For this reason, the solid-state imaging device 12 can generate a signal indicating a two-dimensional distribution of light which has passed through the second microlens 161.

### Fourth Embodiment

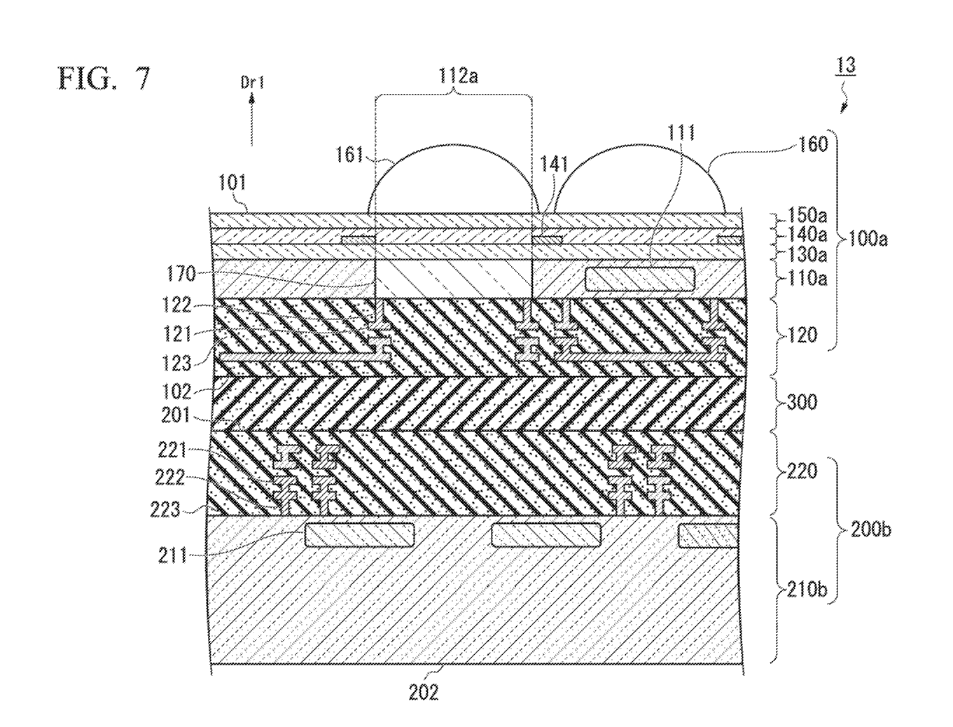

FIG. 7 shows a configuration of a solid-state imaging device 13 according to a fourth embodiment of the present invention. In FIG. 7, a partial cross-section of the solid-state imaging device 13 is shown. With respect to the configuration shown in FIG. 7, a difference front the configuration shown in FIG. 4 will be described.

A wiring pattern of the first wiring 121 is different from the wiring pattern of the first wiring 121 in FIG. 4. The first wiring 121 is disposed to shield the light which has passed through the first photoelectric conversion element 111.

In FIG. 7, the second substrate 200 in FIG. 4 is changed to a second substrate 200b. The second semiconductor layer 210 of the second substrate 200 is changed to a second semiconductor layer 210b in the second substrate 200b. Arrangement positions of the plurality of second photoelectric conversion elements 211 in the second semiconductor layer 210b are different from arrangement positions of the plurality of second photoelectric conversion elements 211 in the second semiconductor layer 210.

Two or more second photoelectric conversion elements 211 are arranged to correspond to each of the plurality of first microlenses 160 and each of the plurality of first photoelectric conversion elements 111. In addition, two err more second photoelectric conversion elements 211 are arranged to correspond to each of the plurality of openings 112a. Positions of each of the plurality of second photoelectric conversion elements 211 in a direction parallel to the first surface 101 of the first substrate 100a are different. A wiring pattern of the second wiring 221 is different from a wiring pattern of the second wiring 221 in FIG. 4.

The light which has passed through the first photoelectric conversion element 111 is shielded by the first wiring 121. For this reason, the light which has passed through the first photoelectric conversion element 111 is not incident on the second photoelectric conversion element 211.

Except for the points described above, the configuration shown in FIG. 7 is the same as the configuration shown in FIG. 4.

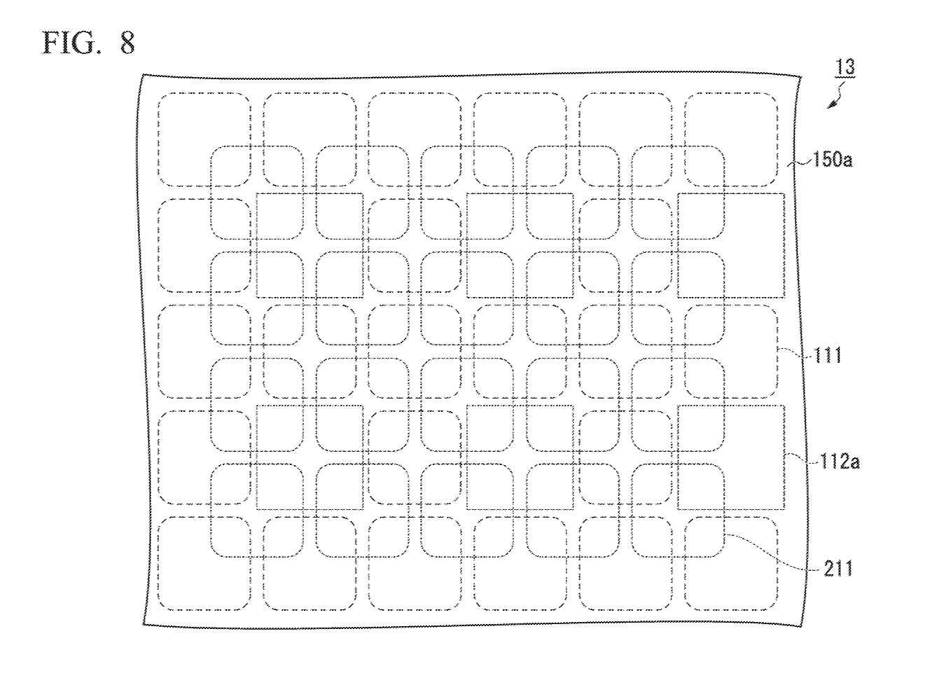

FIG. 8 shows an array of the plurality of first photoelectric conversion elements 111, the plurality of second photoelectric conversion elements 211, and the plurality of openings 112a. FIG. 8 shows the array when the solid-state imaging device 13 is viewed in the direction perpendicular to the first surface 101 of the first substrate 100a. That is, FIG. 8 shows the array when the front of the first substrate 100a of the solid-state imaging device 13 is viewed.

With respect to the configuration shown in FIG. 8, a difference from the configuration shown in FIG. 3 will be described. When the solid-state imaging device 13 is viewed in the direction perpendicular to the first surface 101 of the first substrate 100a, the center of the first photoelectric conversion element 111 does not coincide with the center of the second photoelectric conversion element 211, and the center of the opening 112a does not coincide with the center of the second photoelectric conversion element 211. When the solid-state imaging device 13 is viewed in the direction perpendicular to the first surface 101 of the first substrate 100a, the second photoelectric conversion element 211 deviates in a row direction and a column direction with respect to the first photoelectric conversion element 111. For this reason, two adjacent second photoelectric conversion elements 211 overlap one first photoelectric conversion element 111. In addition, two adjacent second photoelectric conversion elements 211 overlap one opening 112a. The arrangement intervals of the plurality of first photoelectric conversion elements 111 are the same as the arrangement intervals of the plurality of second photoelectric conversion elements 211.

Except for the points described above, the configuration shown in FIG. 8 is the same as the configuration shown in FIG. 3.

The plurality of second photoelectric conversion elements 211 are arranged to correspond to one second microlens 161. For this reason, the second photoelectric conversion element 211 can function as the image surface phase difference autofocus pixel.

When the solid-state imaging device 13 is viewed in the direction perpendicular to the first surface 101 of the first substrate 100a, the second photoelectric conversion element 211 may deviate only in one of the row direction and the column direction with respect to the first photoelectric conversion element 111.

In the fourth embodiment, each of the plurality of second photoelectric conversion elements 211 is disposed in a region corresponding to any one of the plurality of openings 112a. For this reason, the light which has passed through the opening 112a, that is, the light which has passed through the transparent layer 170, is likely to be incident on the second photoelectric conversion element 211. As a result, the solid-state imaging device 13 can increase the amount of light incident on the second photoelectric conversion element 211.

In the fourth embodiment, two or more second photoelectric conversion elements 211 are arranged to correspond to each of the plurality of openings 112a. For this reason, the solid-state imaging device 13 can generate a signal indicating the two-dimensional distribution of light which has passed through the second microlens 161.

### Fifth Embodiment

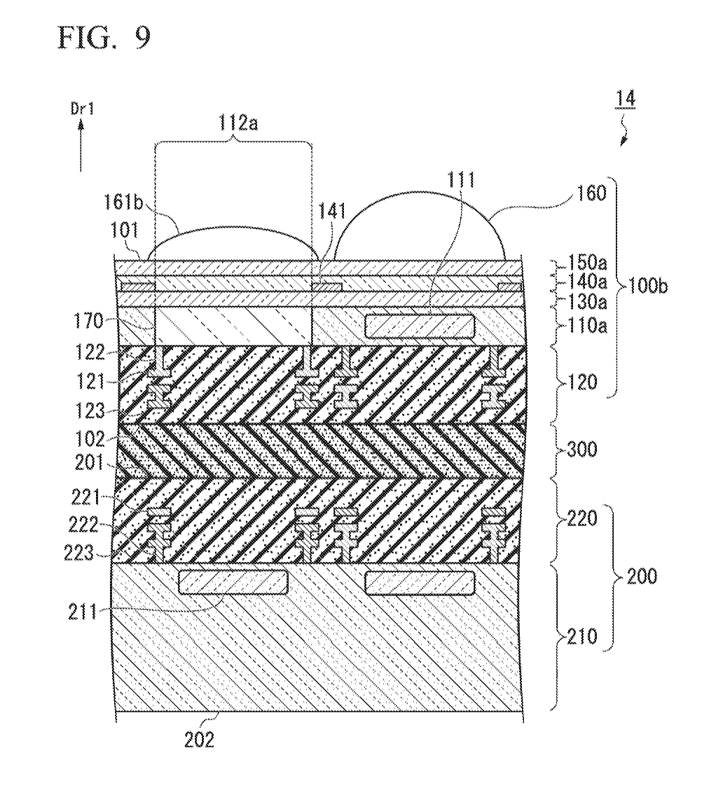

FIG. 9 shows a configuration of a solid-state imaging device 14 according to a fifth embodiment of the present invention. FIG. 9 shows a partial cross-section of the solid-state imaging device 14. With respect to the configuration shown in FIG. 9, a difference from the configuration shown in FIG. 4 will be described.

In FIG. 9, the first substrate 100a in FIG. 4 is changed to a first substrate 100b. The second microlens 161 in the first substrate 100a is changed to a second microlens 161b in the first substrate 100b.

The first substrate 100b includes a plurality of first microlenses 160. Each of the plurality of first microlenses 160 is disposed at a position corresponding to each of the plurality of first photoelectric conversion elements 111. The first substrate 100b further includes a plurality of second microlenses 161b. Each of the plurality of second microlenses 161b is disposed at a position corresponding to one of the plurality of openings 112a. A second curvature of each of the plurality of second microlenses 161b is smaller than a first curvature of each of the plurality of first microlenses 160.

A second curvature radius of each of the plurality of second microlenses 161b is larger than a first curvature radius of each of the first microlenses 160. A shape of the first microlens 160 suitable for a distance between the first microlens 160 and the first photoelectric conversion element 111 is set. The shape of the first microlens 160 is based on a curvature of the first microlens 160. The curvature of the first microlens 160 is set so that the amount of light incident on the first photoelectric conversion element 111 relatively increases. On the other hand, a shape of the second microlens 161b suitable for a distance between the second microlens 161b and the second photoelectric conversion element 211 is set. The shape of the second microlens 161b is based on a curvature of the second microlens 161b. The curvature of the second microlens 161b is set so that the amount of light incident on the second photoelectric conversion element 211 relatively increases.

Except for the points described above, the configuration shown in FIG. 9 is the same as the configuration shown in FIG. 4.

In the solid-state imaging device 14, the second photoelectric conversion element 211 is disposed in a region corresponding to the first photoelectric conversion element 111 and a region corresponding to the opening 112a. However, the second photoelectric conversion element 211 need not be arranged in a region corresponding to the first photoelectric conversion element 111.

The solid-state imaging device according to each aspect of the present invention need not include a constituent corresponding to a plurality of second microlenses 161b.

In the fifth embodiment, each of the second photoelectric conversion elements 211 is disposed in a region corresponding to any one of the plurality of openings 112a. For this reason, the light which has passed through the opening 112a, that is, the light which has passed through the transparent layer 170, is likely to be incident on the second photoelectric conversion element 211. As a result, the solid-state imaging device 14 can increase the amount of light incident on the second photoelectric conversion element 211.

In the fifth embodiment, a second curvature of the second microlens 161b is smaller than a first curvature of the first microlens 160. For this reason, the solid-state imaging device 14 can increase the amount of light incident on the second photoelectric conversion element 211.

### Sixth Embodiment

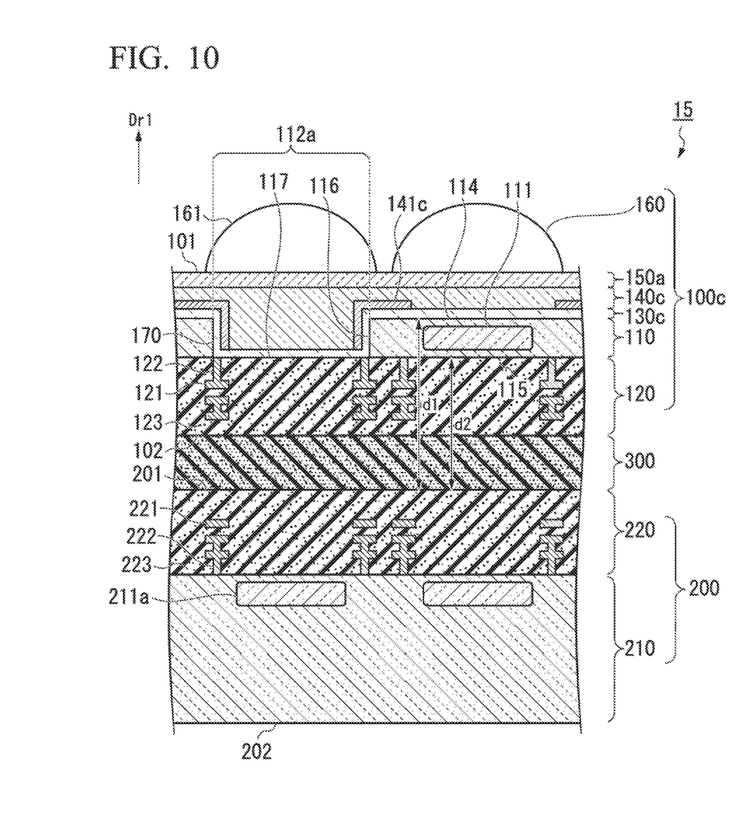

FIG. 10 shows a configuration of the solid-state imaging device 15 according to the sixth embodiment of the present invention. FIG. 10 shows a partial cross-section of the solid-state imaging device 15. With respect to the configuration shown in FIG. 10, a difference from the configuration shown in FIG. 4 will be described.

In FIG. 10, the first substrate 100a in FIG. 4 is changed to a first substrate 100c. The first semiconductor layer 110a in the first substrate 100a is changed to a first semiconductor layer 110 in the first substrate 100c. The anti-reflection film 130a in the first substrate 100a is changed to an anti-reflection film 130c in the first substrate 100c. The transparent resin layer 140a in the first substrate 100a is changed to a transparent resin layer 140c in the first substrate 100c.

The first semiconductor layer 110 includes a first surface 114 and a second surface 115. The first surface 114 and the second surface 115 face in opposite directions. The first surface 114 of the first semiconductor layer 110 is in contact with the anti-reflection film 130c. The second surface 115 of the first semiconductor layer 110 is in contact with the first wiring layer 120. The opening 112a is disposed in the first semiconductor layer 110. The opening 112a has a side surface 116 and a bottom surface 117. The side surface 116 of the opening 112a is the side surface of the first semiconductor layer 110. The bottom surface 117 of the opening 112a is the surface of the first wiring layer 120.

The anti-reflection film 130c is disposed to cover the first surface 114 of the first semiconductor layer 110 and the opening 112a. The transparent resin layer 140c is disposed to cover a surface of the anti-reflection film 130c. A thickness of the transparent resin layer 140c in a region in which the opening 112a is disposed is larger than a thickness of the transparent resin layer 140c in a region which the first semiconductor layer 110 is disposed. A light absorption coefficient of the transparent resin layer 140c is smaller than a light absorption coefficient of the first semiconductor layer 110. Therefore, the transparent resin layer 140c does not absorb light as easily as the first semiconductor layer 110. A surface of the transparent resin layer 140c is planarized.

The light shielding film 141 in the transparent resin layer 140a is changed to a light shielding 141c in the transparent resin layer 140c. The light shielding film 141c is disposed in regions corresponding to the side surface 116 of the opening 112a. The light shielding film 141c is disposed on the anti-reflection film 130c disposed on the side surface 116 of the opening 112a. The light shielding film 141c is disposed in a region corresponding to a portion of the first surface 114 of the first semiconductor layer 110. The light shielding film 141c is disposed on the anti-reflection film 130c disposed on a portion of the first surface 114 of the first semiconductor layer 110. When the solid-state imaging device 15 is viewed in a direction perpendicular to a first surface 101 of the first substrate 100c, the light shielding film 141c and the first photoelectric conversion element 111 do not overlap. The light shielding film 141c is disposed so as not to shield most of the light which has passed through the first microlens 160.

Except for the points described above, the configuration shown in FIG. 10 is the same as the configuration shown in FIG. 4.

In the solid-state imaging device 15, the second photoelectric conversion element 211 is disposed in a region corresponding to the first photoelectric conversion element 111 and a region corresponding to the opening 112a. However, the second photoelectric conversion element 211 need not be disposed in a region corresponding to the first photoelectric conversion element 111.

The light shielding film 141c is disposed in a first region corresponding to the side surface 116 of the opening 112a, and a second region corresponding to a portion of the first surface 114 of the first semiconductor layer 110. The light shielding film 141c may be disposed in only one of the first region and the second region.

As described above, the first substrate 100c includes the light shielding film 141c disposed in the region corresponding to the side surface 116 of the opening 112a. The first semiconductor layer 110 includes the first surface 114 (first main surface) and the second surface 115 (second main surface). The second substrate 200 includes the first surface 201 (third main surface). A first distance d1 between the first surface 114 of the first semiconductor layer 110 and the first surface 201 of the second substrate 200 is larger than a second distance d2 between the second surface 115 of the first semiconductor layer 110 and the first surface 201 of the second substrate 200. The light shielding film 141c is disposed in a region corresponding to a portion of the first surface 114 of the first semiconductor layer 110.

The solid-state imaging device according to each aspect of the present invention need not include a constituent corresponding to at least one of the anti-reflection film 130c and the transparent resin layer 140c.

In the sixth embodiment, each of the plurality of second photoelectric conversion elements 211 is disposed in a region corresponding to any one of the plurality of openings 112a. For this reason, the light which has passed through the opening 112a is likely to be incident on the second photoelectric conversion element 211. As a result, the solid-state imaging device 15 can increase the amount of the light incident on the second photoelectric conversion element 211.

In the sixth embodiment, the light shielding film 141c is disposed. For this reason, light which has passed through the second microlens 161 and is incident on the first photoelectric conversion element 111 is suppressed.

### Seventh Embodiment

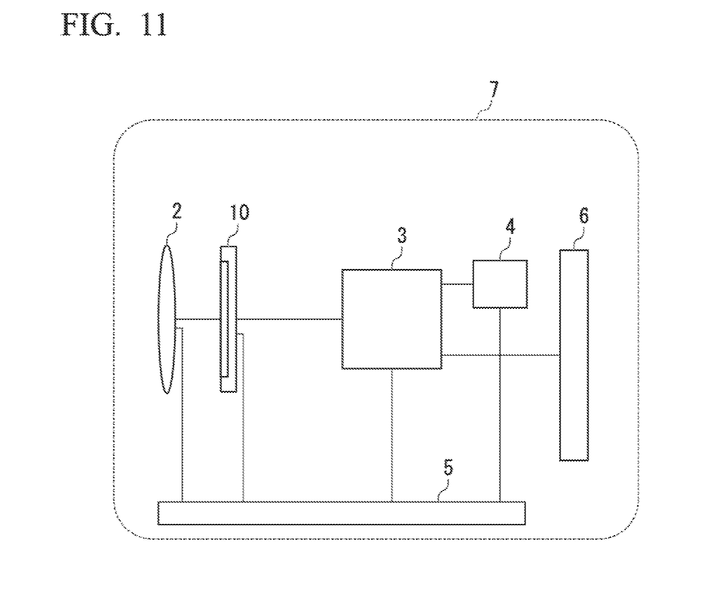

FIG. 11 shows a configuration of an imaging apparatus 7 according to a seventh embodiment of the present invention. The imaging apparatus 7 has only to be an electronic device having an imaging function. For example, the imaging apparatus 7 is any one of a digital camera, a digital video camera, an endoscope, and a microscope. As show in FIG. 11, the imaging apparatus 7 includes the solid-state imaging device 10, a lens unit 2, an image signal processing device 3, a recording device 4, a camera control device 5, and a display device 6.

The solid-state imaging device 10 is the solid-state imaging device 10 of the first embodiment. Instead of the solid-state imaging device 10, any one of the solid-state imaging device 11, the solid-state imaging device 12, the solid-state imaging device 13, the solid-state imaging device 14, and the solid-state imaging device 15 may be used. The lens unit 2 has a zoom lens and a focus lens. The lens unit 2 forms a subject image based on the light from a subject on a light-receiving surface of the solid-state imaging device 10. The subject image is formed on the light-receiving surface of the solid-state imaging device 1 on the basis of the light captured through the lens unit 2. The solid-state imaging device 10 converts the subject image formed on the light-receiving surface into a signal such as an imaging signal, and outputs the signal.

The image signal processing device 3 performs predetermined processing on the signal output from the solid-state imaging device 10. The processing performed by the image signal processing device 3 is conversion into image data, various corrections of image data, compression of image data, and the like.

The recording device 4 has a semiconductor memory and the like for recording or reading image data. The recording device 4 can be attached to and detached from the imaging apparatus 7. The display device 6 displays an image based on image data processed by the image signal processing device 3 or image data read from the recording device 4.

The camera control device 5 entirely controls the imaging apparatus 7. An operation of the camera control device 5 is specified in a program stored in the ROM embedded in the imaging apparatus 7. The camera control device 5 reads this program and performs various types of control according to what the program specifies.

As described above, the imaging apparatus 7 includes the solid-state imaging device 10. The imaging apparatus according to each aspect of the present invention need not have a constituent corresponding to at least one of the lens unit 2, the image signal processing device 3, the recording device 4, the camera control device 5, and the display device 6.

In the seventh embodiment, the solid-state imaging device 10 can increase the amount of light incident on the second photoelectric conversion element 211 in the same manner as in the first embodiment.

While preferred embodiments of the invention have been described and shown above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A solid-state imaging device, comprising:
a first substrate and
a second substrate stacked on the first substrate,
wherein the first substrate has a first semiconductor layer including a plurality of first photoelectric conversion elements and a plurality of openings,
the second substrate has a second semiconductor layer including a plurality of second photoelectric conversion elements,
the plurality of openings penetrate the first semiconductor layer, and
each of the second photoelectric conversion elements included in at least a portion of the plurality of second photoelectric conversion elements is disposed in a region corresponding to any one of the plurality of openings.

2. The solid-state imaging device according to claim 1,
wherein the first substrate further includes light shielding films arranged in regions corresponding to side surfaces of the opening.

3. The solid-state imaging device according to claim 2,
wherein the first semiconductor layer includes a first main surface and a second main surface,
the second substrate includes a third main surface,
a distance between the first main surface and the third main surface is larger than a distance between the second main surface and the third main surface, and
the light shielding film is disposed in a region corresponding to a portion of the first main surface.

4. The solid-state imaging device according to claim 1,
wherein the first substrate further includes a transparent layer made of a transparent material filling the opening.

5. The solid-state imaging device according to claim 1,
wherein the first substrate further includes a plurality of first microlenses, each of the plurality of first microlenses being disposed at a position corresponding to one of the plurality of first photoelectric conversion elements,
the first substrate further includes a plurality of second microlenses, each of the plurality of second microlenses being disposed at a position corresponding to one of the plurality of openings, and
a curvature of each of the plurality of second microlenses is smaller than a curvature of each of the plurality of first microlenses.

6. The solid-state imaging device according to claim 1,
wherein two or more of the second photoelectric conversion elements are disposed in a region corresponding to any one of the plurality of openings.

7. An imaging apparatus which includes the solid-state imaging device according to claim 1.
